(19) United States
(12) Patent Application Publication
(10) Pub. No.: US 2009/0149020 A1
(43) Pub. Date: Jun. 11, 2009

(54) METHOD OF MANUFACTURING A SEMICONDUCTOR DEVICE

(75) Inventors: Takeshi HAYASHI, Tokyo (JP); Takuya Futase, Tokyo (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/328,658

(22) Filed: Dec. 4, 2008

(30) Foreign Application Priority Data
Dec. 6, 2007 (JP) 2007-315522

(51) Int. Cl. H01L 21/44; H01L 21/31

(52) U.S. Cl. 438/653; 438/760; 438/762; 257/E21.24; 257/E21.295

(57) ABSTRACT

A technology is provided which allows, in a coupling portion obtained by burying a conductive material within a coupling hole bored in an insulating film, the removal of a natural oxide film on the surface of a silicide layer which is present at the bottom portion of the coupling hole. A coupling hole is bored in an interlayer insulating film (first and second insulating films) to expose the surface of a nickel silicide layer at the bottom portion of the coupling hole. Then, reduction gases including a HF gas and a NH₃ gas is supplied to the principal surface of a semiconductor wafer to form a product by a reduction reaction, and remove the natural oxide film on the surface of the nickel silicide layer. At this time, the flow rate ratio (HF/NH₃ gas flow rate ratio) between the NF gas and the NH₃ gas is adjusted to be more than 1 and not more than 5. Preferably, the temperature of the semiconductor wafer is adjusted to be not more than 30° C. Thereafter, a heating process is performed at 400° C. to the semiconductor wafer to remove the product remaining on the principal surface of the semiconductor wafer, and subsequently form a barrier metal film.

### CROSS-REFERENCE TO RELATED APPLICATIONS

The disclosure of Japanese Patent Application No. 2007-315522 filed on Dec. 6, 2007 including the specification, drawings and abstract is incorporated herein by reference in its entirety.

### BACKGROUND OF THE INVENTION

The present invention relates to a technology for manufacturing a semiconductor device and, more particularly, to a technology which is effective when applied to a manufacturing process of a semiconductor device in which a metal film is buried within a coupling hole bored in an insulating film via a barrier metal film.

In Japanese Unexamined Patent Publication No. 2004-363402, a method is disclosed which forms a Ti layer at least on the inner wall and bottom portion of a contact hole extending through an insulating layer, further forms a TiN layer over the Ti layer by nitriding the Ni layer using N radicals, and then buries a conductive layer within the contact hole (see Patent Document 1).

In Japanese Unexamined Patent Publication No. 2006-179645, a method is disclosed which forms a contact hole in an interlayer insulating film, forms a Ti film so as to cover the contact hole, and then forms a TiN film on the bottom surface of the contact hole by performing a process of plasma nitridation (see Patent Document 2).

In Japanese Unexamined Patent Publication No. 2005-79543, a method is disclosed which forms a Ti film over a substrate to be processed by CVD, oxidizes the surface of the Ti film, subsequently performs a nitridation process with respect to the surface of the Ti film, and then deposits a TiN film (see Patent Document 3).

### [Patent Document 1]

Japanese Unexamined Patent Publication No. 2004-363402 (paragraphs [0026] to [0028], FIGS. 4 and 5)

### [Patent Document 2]

Japanese Unexamined Patent Publication No. 2006-179645 (paragraphs [0038] to [0040], FIG. 2)

### [Patent Document 3]

Japanese Unexamined Patent Publication No. 2005-79543 (paragraphs [0044] to [0048], FIG. 5)

### SUMMARY OF THE INVENTION

For coupling between a semiconductor substrate and an interconnect in a semiconductor device, there is used a conductive member buried within a coupling hole formed between the semiconductor substrate and the interconnect to extend through an insulating film, e.g., a plug made of tungsten. On the surface of the semiconductor substrate in contact with the bottom portion of the coupling hole, a silicide layer which allows the formation of a low-resistance shallow junction is formed. Among silicide layers, a nickel silicide (NiSi) layer has a low resistance ranging from 14 to 20 μO·cm, and can be formed with a salicide technology using a relatively low temperature of, e.g., 400 to 600° C. Therefore, the adoption of the nickel silicide layer to a semiconductor element which is required to be miniaturized has been examined in recent years.

In general, a barrier metal film having a laminated structure in which a titanium nitride film is deposited over a titanium film is formed between a plug buried within a coupling hole and a nickel silicide layer formed on the surface of a semiconductor substrate. Because the titanium film allows oxygen atoms to be solid-dissolved therein up to 12 at %, it is used as a reductant for the surface of the nickel silicide layer, and has the function of reducing the contact resistance with the nickel silicide layer. On the other hand, the titanium nitride film has the function of suppressing or preventing the diffusion of atoms composing the plug.

However, even when the titanium film functioning as the reductant is formed over the nickel silicide layer, a natural oxide film deposited on the surface of the nickel silicide layer cannot be completely removed, and there is a technological problem such as fluctuations or an increase in the contact resistance between the barrier metal film and the nickel silicide layer.

An object of the present invention is to provide a technology which allows, in a coupling portion obtained by burying a conductive material within a coupling hole bored in an insulating film, the removal of a natural oxide film on the surface of a silicide layer which is present at the bottom portion of the coupling hole.

The above and other objects and novel features of the present invention will become apparent from the description of the present specification and the accompanying drawings.

As shown below, a brief description will be given of an embodiment of the invention disclosed in the present application.

The present embodiment is a method of manufacturing a semiconductor device which includes forming an insulating film over a principal surface of a semiconductor wafer, and forming a plug within a coupling hole bored in the insulating film. First, the coupling hole is bored in the insulating film formed over the principal surface of the semiconductor wafer to expose a surface of a silicide layer at a bottom portion of the coupling hole. Subsequently, reduction gases including a HF gas and a NH₃ gas are supplied to the principal surface of the semiconductor wafer to form a reaction product. As a process condition, the flow rate ratio (HF/NH₃ gas flow rate ratio) between the HF gas and the NH₃ gas is adjusted to be more than 1 and not more than 5. At this time, the temperature of the semiconductor wafer is preferably not more than 30° C. Thereafter, a heating process is performed with respect to the semiconductor wafer to remove the reaction product.

The following is a brief description of an effect achievable by the embodiment of the invention disclosed in the present application.

In the coupling portion obtained by burying the conductive material within the coupling hole bored in the insulating film, a natural oxide film on the surface of the silicide layer which is present at the bottom portion of the coupling hole can be removed.

### BRIEF DESCRIPTION OF THE DRAWINGS

FIG. 1 is a principal-portion cross-sectional view of a semiconductor substrate showing a manufacturing process of a CMOS device according to an embodiment of the present invention;

FIG. 2 is a principal-portion cross-sectional view of the same portion as shown in FIG. 1 during the manufacturing process of the CMOS device, which is subsequent to FIG. 1;

FIG. 3 is a principal-portion cross-sectional view of the same portion as shown in FIG. 1 during the manufacturing process of the CMOS device, which is subsequent to FIG. 2;

FIG. 4 is a principal-portion cross-sectional view of the same portion as shown in FIG. 1 during the manufacturing process of the CMOS device, which is subsequent to FIG. 3;

FIG. 5 is a principal-portion cross-sectional view of the same portion as shown in FIG. 1 during the manufacturing process of the CMOS device, which is subsequent to FIG. 4;

FIG. 6 is a schematic plan view of a film deposition apparatus for a barrier metal film according to the embodiment;

FIG. 7 is a graph showing the relationship between a ΔT (Amount of Scraping at Upper Surface of Coupling Hole)/ΔB (Amount of Scraping at Bottom Surface of Coupling Hole) ratio in a coupling hole with an aspect ratio of 5 and a HF/NH₃ gas flow rate ratio;

FIG. 8 is a graph showing the relationship between the ΔT (Amount of Scraping at Upper Surface of Coupling Hole)/ΔB (Amount of Scraping at Bottom Surface of Coupling Hole) ratio in the coupling hole with an aspect ratio of 5 and the temperature of a wafer stage;

FIG. 9 is a graph showing the relationship between the etching speed of an oxide film formed on the surface of a semiconductor wafer and the HF/NH₃ gas flow rate ratio;

FIG. 10 is a process step chart of a first film deposition method in a barrier-metal-film depositing process according to the embodiment;

FIG. 11 is a process step chart of a second film deposition method in the barrier-metal-film depositing process according to the embodiment;

FIG. 12 is a process step chart of a third film deposition method in the barrier-metal-film depositing process according to the embodiment;

FIG. 13 is a principal-portion enlarged cross-sectional view showing a barrier metal film and a plug within a coupling hole during the manufacturing process of the CMOS device, which is subsequent to FIG. 5;

FIG. 14 is a principal-portion enlarged cross-sectional view of the same portion as shown in FIG. 13 during the manufacturing process of the CMOS device, which is subsequent to FIG. 5;

FIG. 15 is a principal-portion enlarged cross-sectional view of the same portion as shown in FIG. 13 during the manufacturing process of the CMOS device, which is subsequent to FIG. 5;

FIG. 16 is a principal-portion enlarged cross-sectional view of the same portion as shown in FIG. 13 during the manufacturing process of the CMOS device, which is subsequent to FIG. 5;

FIG. 17 is a process step chart of a thermal CVD film deposition method for a titanium nitride film according to the embodiment;

FIG. 18 is a principal-portion enlarged cross-sectional view of the inside of the coupling hole during the manufacturing process of the CMOS device, which is subsequent to FIGS. 13, 14, 15, or 16;

FIG. 19 is a process step chart of a first film deposition method in a tungsten-film depositing process according to the embodiment;

FIG. 20 is a process step chart of a second film deposition method in the tungsten-film depositing process according to the embodiment;

FIG. 21 is a process step chart of a third film deposition method in the tungsten-film depositing process according to the embodiment;

FIG. 22 is a principal-portion enlarged cross-sectional view of the same portion as shown in FIG. 1 during the manufacturing process of the CMOS device, which is subsequent to FIG. 18;

FIG. 23 is a principal-portion enlarged cross-sectional view of the same portion as shown in FIG. 1 during the manufacturing process of the CMOS device, which is subsequent to FIG. 22;

FIG. 24 is a principal-portion enlarged cross-sectional view of the same portion as shown in FIG. 1 during the manufacturing process of the CMOS device, which is subsequent to FIG. 23; and

FIG. 25 is a principal-portion enlarged cross-sectional view of the same portion as shown in FIG. 1 during the manufacturing process of the CMOS device, which is subsequent to FIG. 24.

### DESCRIPTION OF THE PREFERRED EMBODIMENTS

If necessary for the sake of convenience, the present embodiment will be described by dividing it into a plurality of sections or implementations. However, they are by no means irrelevant to each other unless shown particularly explicitly, and are mutually related to each other such that one of the sections or implementations is a variation or a detailed or complementary description of some or all of the others. When the number and the like of elements (including the number, numerical value, amount, and range thereof) are referred to in the present embodiment, they are not limited to specific numbers unless shown particularly explicitly or unless they are obviously limited to specific numbers in principle. The number and the like of the elements may be not less than or not more than specific numbers. It will easily be appreciated that, in the present embodiment, the components thereof (including also elements, steps, and the like) are not necessarily essential unless shown particularly explicitly or unless the components are considered to be obviously essential in principle. Likewise, when the configurations, positional relationship, and the like of the components are referred to in the present embodiment, the configurations and the like are assumed to include those substantially proximate or similar thereto unless shown particularly explicitly or unless obviously they do not in principle. The same shall apply to the foregoing numeric values and the range.

In the present embodiment, a MISFET (Metal Insulator Semiconductor Field Effect Transistor) which represents a field effect transistor will be abbreviated as a MIS, a p-type MISFET will be abbreviated as a pMIS, and an n-type MISFET will be abbreviated as an nMIS. Even when there is a reference to a MOS for the sake of convenience, a non-oxide film will not be excluded. In the present embodiment, when a wafer is mentioned, it primarily indicates a Si (Silicon) single crystal wafer, but the wafer is not limited thereto. It is assumed that the wafer broadly indicates a SOI (Silicon On Insulator) wafer, an insulating film substrate for the formation of an integrated circuit thereon, or the like. The shape of the wafer is not limited to a circular shape or a substantially circular shape, either. It is also assumed that the shape of the wafer embraces a square shape, a rectangular shape, and the like. It will be easily appreciated that, when a silicon film, a silicon element, a silicon member, or the like is mentioned, it not only indicates pure silicon, but also embraces silicon containing an impurity, an alloy (including strained silicon) containing silicon as a main component such as SiGe or SiGeC, and silicon containing an additive unless the silicon film, the silicon element, the silicon member, or the like obviously indicates only pure silicon, or unless it is explicitly shown that the silicon film, the silicon element, the silicon member, or the like indicates only pure silicon. It will also be easily appreciated that, when polysilicon or the like is mentioned, it not only indicates typical polysilicon, but also embraces amorphous silicon and the like unless polysilicon obviously indicates only typical polysilicon, or unless it is explicitly shown that polysilicon indicates only typical polysilicon.

Throughout the drawings for illustrating the present embodiment, parts having the same function are designated by the same reference numeral in principle, and a repeated description thereof will be omitted. Referring to the drawings, the embodiment of the present invention will be described hereinbelow in detail.

As for a dry cleaning technology, it is disclosed in Japanese Patent Application No. 2006-3704 (filed on Jan. 11, 2006) by Ichinose et al., Japanese Patent Application No. 2006-12355 (filed on Jan. 20, 2006) by Ichinose et al., Japanese Patent Application No. 2006-107780 (filed on Apr. 10, 2006) by Nise et al., and Japanese Patent Application No. 2006-138949 (filed on May 18, 2006) by Nise et. al. Accordingly, a portion overlapping the technology disclosed in the applications mentioned above will not be repeated in principle.

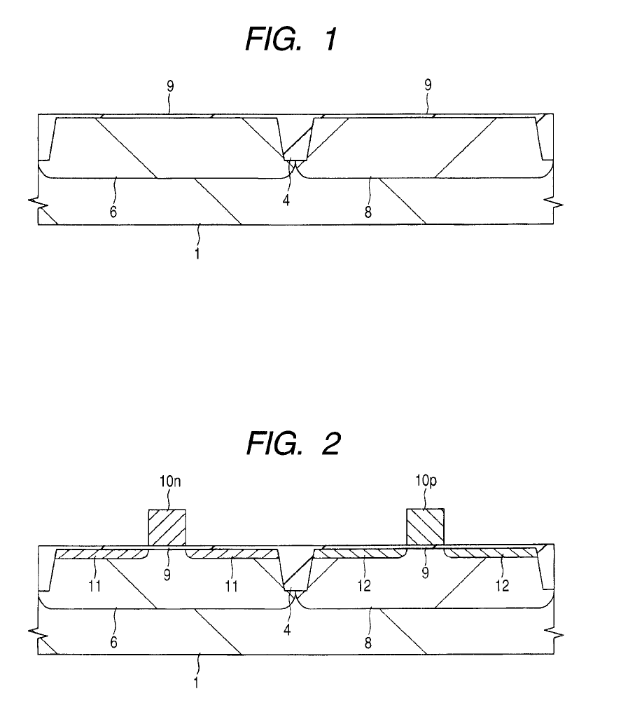

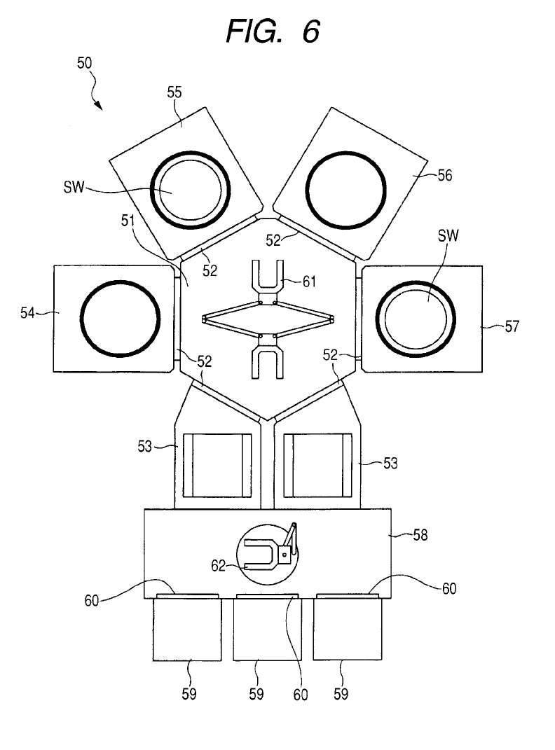

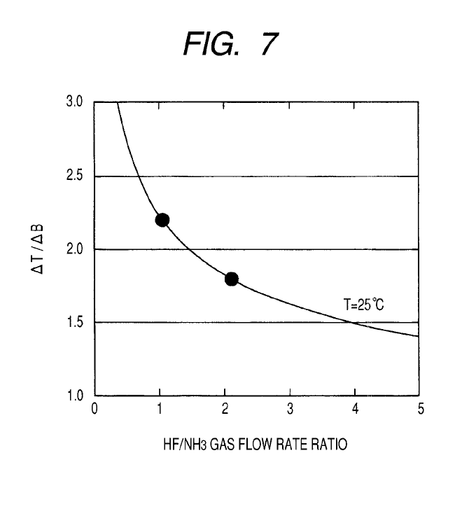

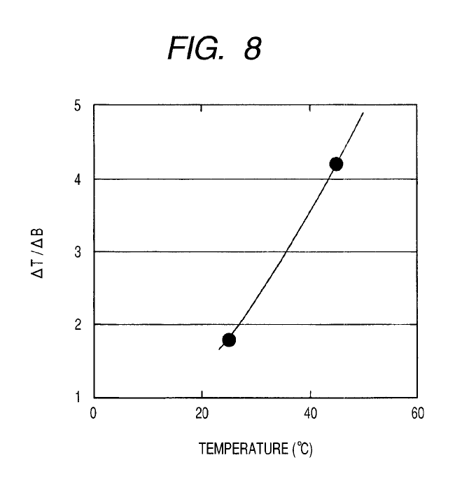

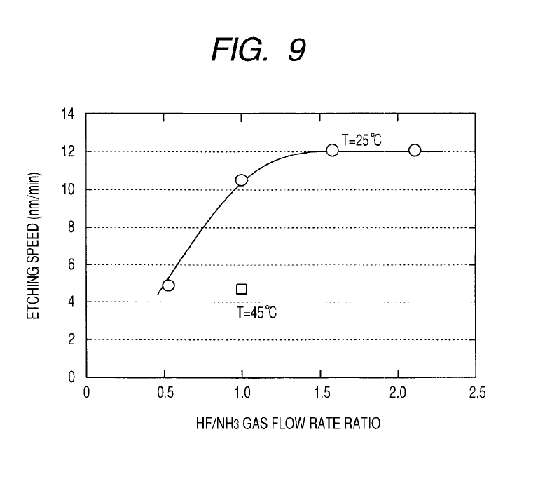

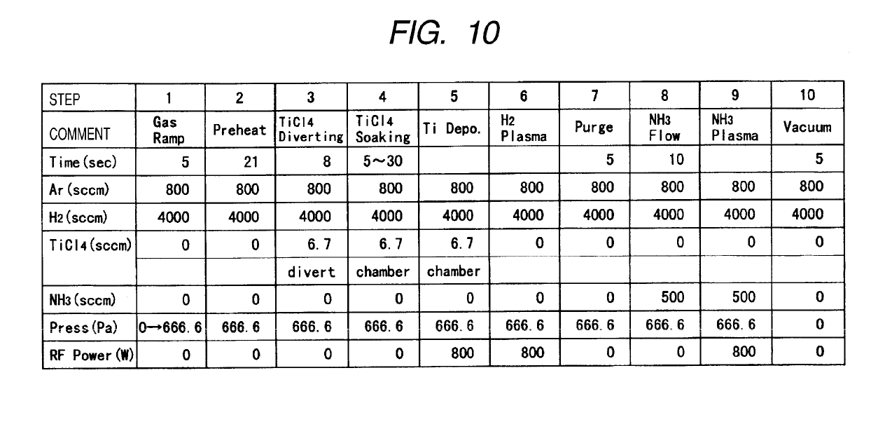

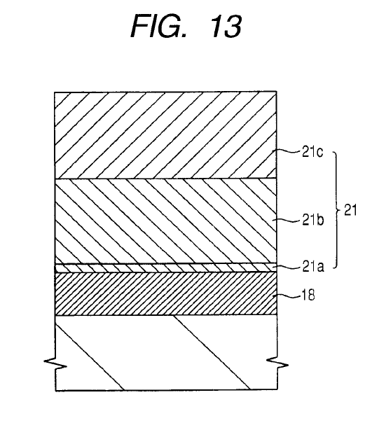

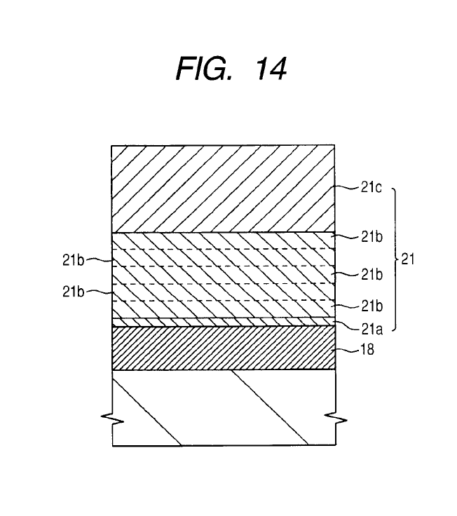

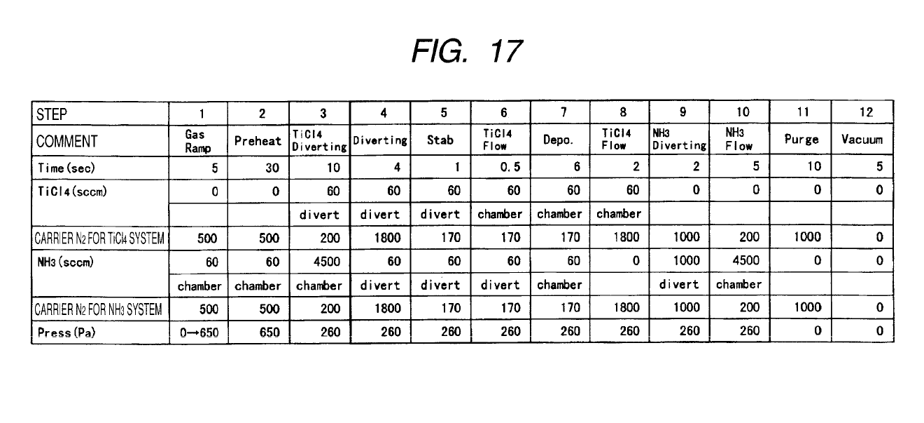

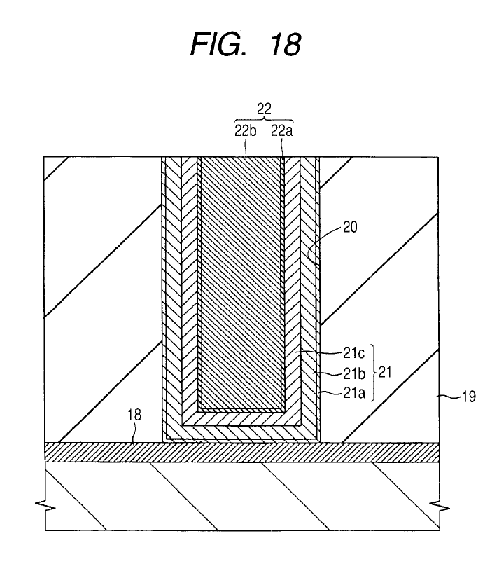

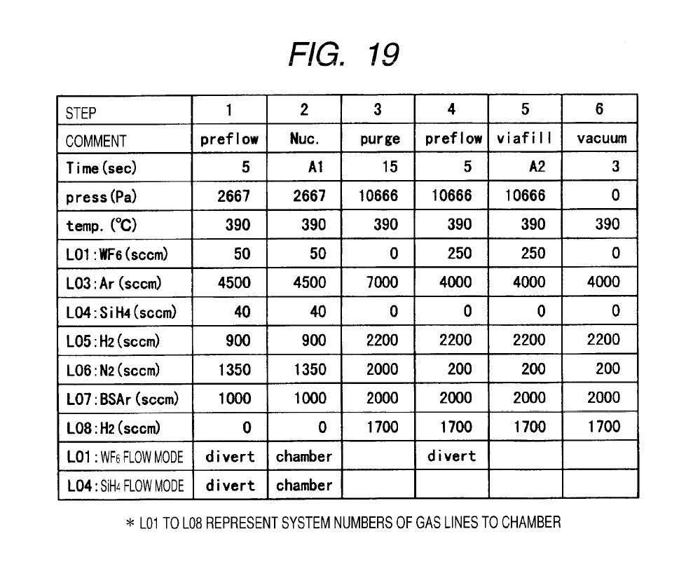

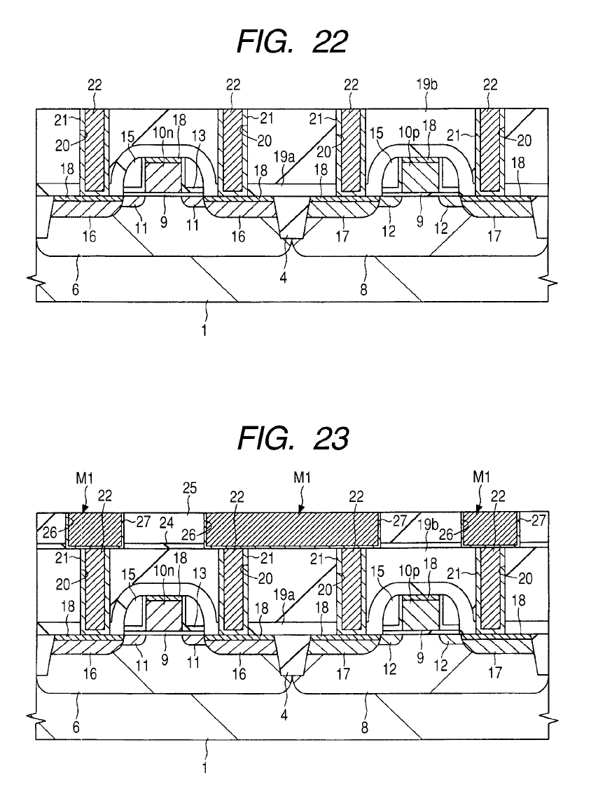

A method of manufacturing a CMOS (Complementary Metal Oxide Semiconductor) device according to the present embodiment will be described with reference to FIGS. 1 through 25. FIGS. 1 through 5 are principal-portion cross-sectional views of the CMOS device. FIG. 6 is a schematic plan view of a film deposition apparatus for a barrier metal film. FIG. 7 is a graph illustrating the relationship between a ΔT (Amount of Scraping at Upper Surface of Coupling Hole)/ΔB (Amount of Scraping at Bottom Surface of Coupling Hole) ratio and a HF/NH₃ gas flow rate ratio. FIG. 8 is a graph illustrating the relationship between the ΔT (Amount of Scraping at Upper Surface of Coupling Hole)/ΔB (Amount of Scraping at Bottom Surface of Coupling Hole) ratio and the temperature of a wafer stage. FIG. 9 is a graph illustrating the relationship between the etching speed of an oxide film formed on the surface of a semiconductor wafer and the HF/NH₃ gas flow rate ratio. FIGS. 10 through 12 are charts showing the process steps of a barrier-metal-film depositing process. FIGS. 13 through 16 are principal-portion enlarged cross-sectional views showing the barrier metal film and a plug within the coupling hole. FIG. 17 is a chart showing the process step of the barrier-metal-film depositing process. FIG. 18 is a principal-portion enlarged cross-sectional view showing the inside of the coupling hole. FIGS. 19 through 21 are charts showing the process steps of a tungsten-film depositing process. FIGS. 22 through 25 are principal-portion cross-sectional views of the CMOS device.

First, as shown in FIG. 1, a semiconductor substrate (a semiconductor thin plate in a generally circular plan shape which is termed a semiconductor wafer) made of, e.g., p-type single crystal silicon is prepared. Next, an isolation region 4 is formed in the principal surface of the semiconductor substrate 1. The isolation region 4 is formed by etching the semiconductor substrate 1 to form a trench at a depth of 0.35 μm, subsequently depositing an insulating film, e.g., a silicon dioxide film over the principal surface of the semiconductor substrate 1 by a CVD (Chemical Vapor Deposition) method, and then removing the silicon dioxide film located outside the trench by a CMP (Chemical Mechanical Polishing) method.

Next, a p-type impurity, e.g., boron is ion implanted into the nMIS formation region of the semiconductor substrate 1 to form a p-type well 6, while an n-type impurity, e.g., phosphorus is ion implanted into the pMIS formation region of the semiconductor substrate 1 to form an n-type well 8. Thereafter, an impurity for controlling the threshold of an nMIS or a pMIS may also be ion implanted appropriately into the p-type well 6 or the n-type well 8.

Next, the surface of the semiconductor substrate 1 is cleaned by wet etching using, e.g., an aqueous hydrofluoric acid solution. Then, the semiconductor substrate 1 is thermally oxidized to form a gate insulating film 9 having a thickness of, e.g., 5 nm on the surface (the respective surfaces of the p-type well 6 and the n-type well 8) of the semiconductor substrate 1.

Next, as shown in FIG. 2, a conductive film for gate electrodes having a thickness of, e.g., 0.14 μm is formed over the gate insulating film 9, and then processed by dry etching using a resist pattern as a mask to form gate electrodes 10n and 10p each made of the conductive film. The conductive film for gate electrodes is made of, e.g., a polysilicon film formed by, e.g., a CVD method. The gate electrode 10n made of a polysilicon film into which an n-type impurity has been introduced is formed in the nMIS formation region. The gate electrode 10p made of a polysilicon film into which a p-type impurity has been introduced is formed in the pMIS formation region.

Next, an n-type impurity, e.g., arsenic is ion implanted into the p-type well 6 to form source/drain extension regions 11 each at a relatively low concentration in a self-aligned manner with respect to the gate electrode 10n of the nMIS. Likewise, a p-type impurity, e.g., boron fluoride is ion implanted into the n-type well 8 to form source/drain extension regions 12 each at a relatively low concentration in a self-aligned manner with respect to the gate electrode 10p of the pMIS. The depth of each of the source/drain extension regions 11 and 12 mentioned above is, e.g., 30 nm.

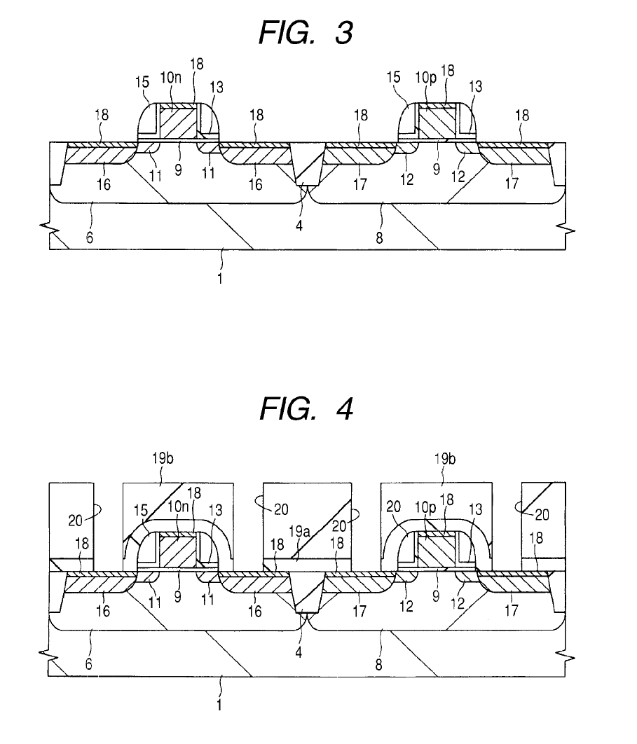

Next, as shown in FIG. 3, a silicon dioxide film 13 having a thickness of, e.g., 10 nm is deposited over the principal surface of the semiconductor substrate 1 by a CVD method, and a silicon nitride film is further deposited over the silicon dioxide film 13 by a CVD method. Subsequently, the silicon nitride film is anisotropically etched by a RIE (Reactive Ion Etching) method to form sidewalls 15 on the respective side walls of the gate electrode 10n of the nMIS and the gate electrode 10p of the pMIS. Thereafter, an n-type impurity, e.g., arsenic is ion implanted into the p-type well 6 to form source/drain diffusion regions 16 each at a relatively high concentration in a self-aligned manner with respect to the gate electrode 10n and the sidewalls 15 of the nMIS. Likewise, a p-type impurity, e.g., boron fluoride is ion implanted into the n-type well 8 to form source/drain diffusion regions 17 each at a relatively high concentration in a self-aligned manner with respect to the gate electrode 10p and the sidewalls 15 of the pMIS. The depth of each of the source/drain diffusion regions 16 and 17 mentioned above is, e.g., 80 nm.

Next, using a salicide technology, a low-resistance nickel silicide (NiSi) layer 18 is formed on each of the respective surfaces of the gate electrode 10n of the nMIS, the source/drain diffusion regions 16, the gate electrode 10p of the pMIS, and the source/drain diffusion regions 17. Although the nickel silicide layer 18 is shown by way of example, another silicide layer, e.g., a nickel alloy silicide layer, a cobalt silicide layer, a tungsten silicide layer, a platinum silicide layer, or the like can also be formed. The nickel silicide layer 18 is formed by, e.g., a method which will be described hereinbelow.

First, a nickel film and a titanium nitride film are successively deposited over the principal surface of the semiconductor substrate 1 by a sputtering method. The thickness of the nickel film is, e.g., 10 nm, and the thickness of the titanium nitride film is, e.g., 15 nm. The titanium nitride film is provided over the nickel film in order to prevent the oxidation of the nickel film. Instead of the titanium nitride film, a titanium film may also be used. Subsequently, a heating process using a RTA (Rapid Thermal Anneal) method is performed at a temperature of, e.g., 350° C. for 30 seconds with respect to the semiconductor substrate 1, thereby causing a selective reaction between the nickel film and the n-type polysilicon film composing the gate electrode 10n of the nMIS, and a selective reaction between the nickel film and the single crystal silicon composing the semiconductor substrate 1 formed with the source/drain diffusion regions 16 of the nMIS to form the nickel silicide layers 18. Likewise, a selective reaction is caused between the nickel film and the p-type polysilicon film composing the gate electrode 10p of the pMIS, and a selective reaction is caused between the nickel film and the single crystal silicon composing the semiconductor substrate 1 formed with the source/drain diffusion regions 17 of the pMIS to form the nickel silicide layers 18. Subsequently, the respective unreacted portions of the nickel films and the titanium nitride films are removed by wet cleaning using a sulfuric acid, wet cleaning using a sulfuric acid and aqueous hydrogen peroxide, or the like. Thereafter, using an RTA method, a heating process is performed at a temperature of, e.g., 550° C. for 30 seconds with respect to the semiconductor substrate 1, thereby reducing the resistance of the nickel silicide layer 18.

Next, as shown in FIG. 4, a silicon nitride film is deposited over the principal surface of the semiconductor substrate 1 by a CVD method to form a first insulating film 19a. Subsequently, a TEOS (Tetra Ethyl Ortho Silicate) film is deposited over the first insulating film 19a by a plasma CVD method to form a second insulating film 19b, and thereby form an interlayer insulating film comprised of the first and second insulating films 19a and 19b. Thereafter, the surface of the second insulating film 19b is polished by a CMP method. Even when a concave and convex configuration has been formed in the surface of the first insulating film 19a due to an underlying level difference, the interlayer insulating film having a planarized surface can be obtained by polishing the surface of the second insulating film 19b by a CMP method.

Next, the first and second insulating films 19a and 19b are etched using a resist pattern as a mask so that coupling holes 20 are formed in predetermined portions, e.g., in the first and second insulating films 19a and 19b located above the gate electrode 10n of the nMIS, the source/drain diffusion regions 16, the gate electrode lop of the pMIS, and the source/drain diffusion regions 17. The diameter of each of the coupling holes 20 is not more than 0.1 μm, and is, e.g., 0.08 μm.

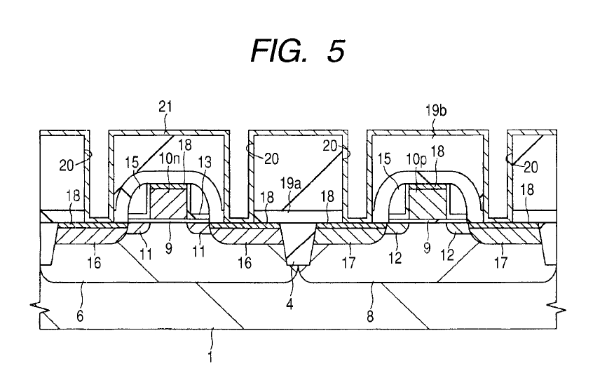

Next, as shown in FIG. 5, a titanium film and a titanium nitride film are successively formed over the principal surface of the semiconductor substrate 1 including the inside of each of the coupling holes 20 to form a barrier metal film 21 made of the resulting laminated layer. Because the titanium film allows oxygen atoms to be solid-dissolved therein up to 12 at %, the titanium film is used as a reductant for the surface of the nickel silicide layer 18, and has the function of reducing the contact resistance with the nickel silicide layer 18. On the other hand, the titanium nitride film has the function of suppressing or preventing the diffusion of atoms composing a metal film buried within each of the coupling holes 20 in the subsequent step. The thickness of the barrier metal film 21 is in a range of, e.g., 3 to 10 nm. In the following description, the titanium film and the titanium nitride film formed thereover will be referred to as the barrier metal film 21, and distinguished from a metal film, e.g., a tungsten film buried within the coupling hole 20 to serve as a main conductive material.

For the deposition of the barrier metal film 21, a film deposition apparatus 50 shown in FIG. 6 is used. The film deposition apparatus 50 is a multi-chamber type having load lock chambers 53 and four chambers 54, 55, 56, and 57 which are provided around a transport chamber 51 via gate valves 52 each as an opening/closing means. On the side of each of the load lock chambers 53 opposite to the transport chamber 51, a wafer transport-in/out chamber 58 is provided. On the side of the wafer transport-in/out chamber 58 opposite to the load lock chambers 53, ports 60 for mounting FOUPs (Front Open Unified Pods) 59 which contain semiconductor wafers SW are provided.

The transport chamber 51 is held at a predetermined degree of vacuum by an exhaust mechanism or the like. At the center portion of the transport chamber 51, a transport robot 61 having a multi-joint arm structure for transporting the semiconductor wafers SW is provided.

The chamber (first chamber) 54 provided in the transport chamber 51 is a chamber for a dry cleaning process. The chamber (second chamber) 55 is a chamber for a heating process performed at a high temperature of not less than, e.g., 150° C. The chambers (third chambers) 56 and 57 are chambers each for the deposition of a barrier metal film. Although the four chambers are provided in the transport chamber 51 of the film deposition apparatus 50, the chambers provided in the transport chamber 51 are not limited thereto. It is also possible to add a chamber for the same purpose or for another purpose.

First, the single semiconductor wafer SW is retrieved from any of the FOUPs 59 by a transport robot 62 disposed in the wafer transport-in/out chamber 58, and transported into any of the load lock chambers 53. Each of the FOUPs 59 is an airtight container for batch transporting the semiconductor wafers SW, and typically contains the semiconductor wafers SW in a batch of 25 pieces, 12 pieces, 6 pieces, or the like. The container outer wall of the FOUP 59 has a hermetically sealed structure except for an extremely fine air pass filter portion thereof, so that dust particles are removed substantially completely. Therefore, even when the semiconductor wafers SW are transported in a class-1000 atmosphere, a class-1 cleanliness can be held in the inside thereof. Docking with the film deposition apparatus 50 is performed in a state where the cleanliness is held by attaching the door of each of the FOUPs 59 to the port 60, and drawing the FOUP 59 into the wafer transport-in/out chamber 58. Subsequently, the load lock chambers 53 are evacuated, and then the semiconductor wafers SW are transported into the transport chamber 51 by the transport robot 61.

Next, the semiconductor wafers SW are vacuum transported by the transfer robot 61 from the transport chamber 51 to the chamber 54 for a dry cleaning process, and placed on a wafer stage provided in the chamber 54. The wafer stage of the chamber 54 is provided with a mechanism of electrostatically adsorbing the wafers and holding them, which allows efficient control of the temperatures of the semiconductor wafers SW. During a dry cleaning process, a reduction gas (seventh reaction gas), e.g., an Ar gas added with a NF gas and a NH₃ gas is introduced into the chamber 54, and supplied to the principal surface of each of the semiconductor wafers SW via a shower head, whereby a natural oxide film formed on the surface of each of the nickel silicide layers 18 is removed by, e.g., a reduction reaction given by (Formula 1) which occurs between the reduction gas and the natural oxide film:

SiO₂+6HF+2NH₃→(NH₄)₂SiF₆+2H₂O (Formula 1).

At this time, a product ((NH₄)₂SiF₆) produced by the reduction reaction remains on the principal surface of the semiconductor wafer SW including the inside of each of the coupling holes 20.

As process conditions during the dry cleaning process, the temperature of the semiconductor wafer (wafer stage), the flow rate of the HF gas, the flow rate of the NH₃ gas, the flow rate of the Ar gas, a pressure, and the like need to be set. Among them, a flow rate ratio (HF/NH₃ gas flow rate ratio) between the HF gas and the NH₃ gas is adjusted to be more than 1 and not more than 5. At this time, the temperature of the semiconductor wafer is preferably not more than 30° C. As an example of the process conditions adopted by the present inventors, there can be listed, e.g., 25° C. as the temperature of the semiconductor wafer, 80 sccm as the flow rate of the HF gas, 38 sccm as the flow rate of the NH₃ gas, 5 sccm as the flow rate of the Ar gas, 1.3 Pa as the pressure, and 2000 V as an ESC voltage.

Next, the semiconductor wafers SW are vacuum transported by the transport robot 61 from the chamber 54 for a dry cleaning process to the chamber 55 for a heating process via the transport chamber 51, and placed on a stage provided in the chamber 55. By placing the semiconductor wafers SW on the stage of the chamber 55, the semiconductor wafers SW are heated at a predetermined temperature so that the product remaining on the principal surface of each of the semiconductor wafers SW is sublimated to be removed. For example, a range of 150 to 400° C. is considered to be proper for a temperature on the principal surface of the semiconductor wafer SW (the temperature is not originally limited to the range by another condition). As a range suitable for mass production, a range of 165 to 350° C. is considered and, further, a range of 180 to 220° C. around 200° C. as a center value is most preferable.

Thereafter, the barrier metal film 21 is formed. However, after the step of the dry cleaning process, the product produced on the bottom and side surfaces of the coupling holes 20 during the dry cleaning process has been removed by performing the heating process at a temperature ranging from 150 to 400° C. with respect to the semiconductor substrate 1. Therefore, it is possible to reduce fluctuations in the contact resistance between the barrier metal film 21 and the nickel silicide layer 18 at the bottom surface of each of the coupling holes 20. It is further possible to prevent the delamination of the barrier metal film 21 at the surface of the coupling hole 20.

In the embodiment according to the present invention, the flow rate ratio (HF/NH₃ flow rate ratio) between the HF gas and the NH₃ gas is regulated to be more than 1 and not more than 5 as the process condition of the dry cleaning process, as described above. At this time, the temperature of the wafer stage is preferably not more than 30° C. A description will be given hereinbelow of the effect obtained by regulating the process condition, and a reason by which the effect is obtained with reference to FIGS. 7 through 9.

In the dry cleaning process, the natural oxide film formed on the surface of the nickel silicide layer 18 is reduced by the chemical reaction shown above in (Formula 1) to produce (NH₄)₂SiF₆. The product is sublimated in the next step of the heating process to be removed. However, because the chemical reaction isotropically proceeds, (NH₄)₂SiF₆ is produced not only on the natural oxide film on the surface of the nickel silicide layer 18, but also on the surface of the second insulating film 19b made of the TEOS (Tetra Ethyl Ortho Silicate) film of the interlayer insulating film forming the coupling holes 20. As a result, after the product is removed, the upper and side surfaces of the coupling holes 20 are also scraped.

When the diameter of each of the coupling holes 20 is enlarged by the scraping of the upper and side surfaces of the coupling hole 20, the distance to the gate electrode 10n of the nMIS or to the gate electrode 10p of the pMIS which is adjacent to the coupling hole 20 is reduced. As a result, a short circuit between the gate electrode 10n or 10p and the metal film buried within the coupling hole 20 becomes a concern. Therefore, a process condition which reduces the amount of scraping of the upper and side surfaces of the coupling hole 20, and also allows the removal of the natural oxide film on the surface of the nickel silicide layer 18 at the bottom surface of the coupling hole 20 is preferable in the dry cleaning process. That is, when the amount of scraping of the oxide film (which is the TEOS film composing the second insulating film 19b in the present embodiment) at the upper surface of each of the coupling holes is assumed to be ΔT, and the amount of scraping of the oxide film (which is the TEOS film composing the second insulating film 19b in the present embodiment) at the bottom surface of the coupling hole is assumed to be ΔB, the selection of a process condition which allows a reduction in ΔT/ΔB ratio provides a process condition which is effective in removing the natural oxide film on the surface of the nickel silicide layer 18 at the bottom surface of the coupling hole 20.

FIG. 7 shows the relationship between the ΔT/ΔB ratio in a coupling hole with an aspect ratio of 5 and the HF/NH₃ gas flow rate ratio. FIG. 8 shows the relationship between the ΔT/ΔB ratio in the coupling hole with an aspect ratio of 5and the temperature of a semiconductor wafer.

As shown in FIG. 7, when the HF/NH₃ gas flow rate ratio becomes not more than 1, the ΔT/ΔB ratio significantly increases so that the HF/NH₃ gas flow rate ratio is preferably more than 1. On the other hand, since a reduction in etching speed is expected, the HF/NH₃ gas flow rate ratio is preferably adjusted to be not more than 5. In addition, as shown in FIG. 8, the ΔT/ΔB ratio increases as the temperature of the semiconductor wafer increases. Since the ΔT/ΔB ratio is about 2.5 when the temperature of the semiconductor wafer is 30° C., the temperature of the semiconductor wafer is preferably not more than 30° C.

Accordingly, by regulating the process conditions of the dry cleaning process such that the HF/NH₃ gas flow rate ratio is more than 1 and not more than 5, and the temperature of the semiconductor wafer is not more than 30° C., it is possible to suppress the enlargement of the diameter of each of the coupling holes 20, and allows the removal of the natural oxide film from the surface of the nickel silicide layer 18 at the bottom surface of the coupling hole 20.

Next, a consideration will be given of the reason by which the effect mentioned above is obtained by adjusting the HF/NH₃ gas flow rate ratio to a value of more than 1 and not more than 5.

FIG. 9 shows the relationship between the etching speed of an oxide film formed on the surface of a semiconductor wafer and the HF/NH₃ gas flow rate ratio. The etching speed is defined herein as an amount of scraping of the oxide film removed by performing a dry cleaning process for a given period of time (e.g., 60 seconds), and subsequently performing a heating process. As shown in FIG. 9, the etching speed is dependent on the HF/NH₃ gas flow rate ratio. As the HF/NH₃ gas flow rate ratio increases, the etching speed increases. However, when the HF/NH₃ gas flow rate ratio exceeds 1, the etching speed becomes substantially constant. This is conceivably because, when the HF/NH₃ gas flow rate ratio is not more than 1, the etching speed is limited by a supply and, when the HF/NH₃ gas flow rate ratio is more than 1, the etching speed is limited by a surface reaction.

The HF gas and the NH₃ gas which are introduced into the chamber for the dry cleaning process are consumed first to reduce the oxide film on the upper surface of each of the coupling holes, and the HF gas and the NH₃ gas which have not been consumed at the upper surface of the coupling hole reach the bottom surface of the coupling hole to reduce the oxide film on the bottom surface of the coupling hole. According, when the HF/NH₃ gas flow rate ratio is not more than 1, the etching speed is conceivably limited by a supply so that the reduction of the oxide film at the upper surface of the coupling hole proceeds to increase ΔT. However, since the HF gas is less likely to be supplied to the bottom surface of the coupling hole, it is presumed that the reduction of the oxide film at the bottom surface of the coupling hole does not proceed. Conversely, when the HF/NH₃ gas flow rate ratio is more than 1, the etching speed is conceivably limited by a surface reaction so that the reduction of the oxide film at the upper surface of the coupling hole proceeds. However, since the HF gas is sufficiently supplied to the bottom surface of the coupling hole, it is presumed that the reduction of the oxide film at the bottom surface of the coupling hole also proceeds to increase ΔB. Therefore, the HF/NH₃ gas flow rate ratio has an optimum range of more than 1 and not more than 5.

Next, a consideration will be given of the reason by which the effect mentioned above is obtained by adjusting the temperature of the semiconductor wafer to a value of not more than 30° C.

The thickness of the product ((NH₄)₂SiF₆) adsorbed on the surface of the oxide film is dependent on the amount of the HF gas and the NH₃ gas adsorbed on the surface of the oxide film. When the temperature of the semiconductor wafer increases, the amount of the adsorbed gases decreases. At this time, the amount of the adsorbed gases decreases at both of the upper surface and bottom surface of each of the coupling holes. However, because the gas concentration at the bottom surface of the coupling hole is lower than at the upper surface thereof, the thickness of the product formed at the bottom surface of the coupling hole conceivably decreases to be smaller than the thickness of the product formed at the top surface of the coupling hole. Therefore, the temperature of the semiconductor wafer has an optimum range of not more than 30° C.

Although the HF gas and the NH₃ gas have been used in the dry cleaning process mentioned above, the reaction gases such as the reduction gases are not limited to the gases mentioned above. Any gas may be used appropriately provided that it reacts with the oxide film at a relatively low temperature to be vaporized. For example, a NF₃ gas and a H₂ gas or a NF₃ gas and a NH₃ gas may also be used appropriately as the reduction gases.

Next, the semiconductor wafers SW are vacuum transported by the transport robot 61 from the chamber 55 for a heating process to the chamber 56 or the chamber 57 for depositing a barrier metal film via the transport chamber 51, and placed on a stage provided in the chamber 56 or the chamber 57.

The film deposition apparatus 50 is provided with the two chambers 56 and 57 having the same function and the same structure for depositing a barrier metal film. Since the two chambers 56 and 57 having the same function and the same structure are provided in the single film deposition apparatus 50, even when one of the two chambers, e.g., the chamber 56 is halted, it is possible to deposit the barrier metal film 21 using the other chamber without halting the film deposition apparatus 50. This allows an improvement in the operation rate of the film deposition apparatus 50.

In the chamber 56 (or the chamber 57) mentioned above, the barrier metal film 21 is deposited over the principal surface of each of the semiconductor wafers SW by a PECVD (Plasma Enhanced Chemical Vapor Deposition) method. Although first to fourth film deposition methods for the barrier metal film 21 will be described herein, the film deposition method for the barrier metal film 21 is not limited thereto, and can be variously changed.

The first film deposition method for the barrier metal film 21 will be described with reference to FIGS. 10 and 13.

[Step 1] First, the semiconductor wafers SW are placed on a stage heated to a predetermined temperature of, e.g., 450° C. by a heater. During the period from Step 1 to Step 10, the stage is constantly heated at a predetermined temperature of, e.g., 450° C. Then, an Ar gas and a H₂ gas are introduced into the chamber to establish a predetermined pressure of, e.g., 667 Pa within the chamber in a predetermined time of, e.g., 5 seconds, which is set in Step 1, by means of an exhaust mechanism. The flow rate of the Ar gas is, e.g., 800 sccm, and the flow rate of the H₂ gas is, e.g., 4000 sccm. [Step 2] After the pressure and the flow rates of the Ar gas and the H₂ gas are set to the predetermined values, each of the wafers is heated for a predetermined time. During the period from Step 2 to Step 9, a predetermined pressure (e.g., 667 Pa) is constantly maintained within the chamber. During the period from Step 2 to Step 10, the Ar gas and the H₂ gas are constantly introduced into the chamber at predetermined flow rates (e.g., 800 sccm and 4000 sccm, respectively). [Step 3] A TiCl₄ gas (first reaction gas) is supplied from a TiCl₄ gas supply source, and caused to flow to the outside immediately before reaching the chamber till the flow rate thereof is stabilized. The flow rate of the TiCl₄ gas is, e.g., 6.7 sccm. [Step 4] After the flow rate of the TiCl₄ gas is stabilized, the TiCl₄ gas is introduced into the chamber to selectively form a titanium film (hereinafter referred to as a thermal reaction Ti film as a first metal film) 21a on the surface of the nickel silicide layer 18 by a thermal reaction. The flow rate of the TiCl₄ gas is, e.g., 6.7 sccm, and a heating process time is, e.g., 5 to 30 seconds. The thickness of the thermal reaction Ti film is, e.g., not more than 1 nm. The thermal reaction Ti film 21a is formed only on the surface of the nickel silicide layer 18 exposed at the bottom portion of each of the coupling holes 20, and is not formed on the side wall of the coupling hole 20 or on the upper surface of the second insulating film 19b. [Step 5] A plasma is generated within the chamber by the application of an RF power to form a titanium film (hereinafter referred to as a plasma reaction Ti film as a second metal film) 21b over the thermal reaction Ti film 21a. The flow rate of the TiCl₄ gas is, e.g., 6.7 sccm. The RF power is, e.g., 800 W. A film deposition time is, e.g., 25 seconds. The thickness of the plasma reaction Ti film 21b is not less than 2 nm, and is in a range of, e.g., 3 to 10 nm. [Step 6] Only the introduction of the TiCl₄ gas into the chamber is stopped, and a plasma process (first plasma process) using a H₂ gas (second reaction gas) is performed with respect to the plasma reaction Ti film 21b to reduce the chlorine concentration of the plasma reaction Ti film 21b. A plasma process time is, e.g., 5 seconds.

[Step 7] The application of the RF power is stopped, and the TiCl₄ gas is exhausted from the inside of the chamber. [Step 8] A NH₃ gas (third reaction gas) is introduced into the chamber to nitride the surface of the plasma reaction Ti film 21b by a thermal reaction. The flow rate of the NH₃ gas is, e.g., 500 sccm, and a heating process time is, e.g., 10 seconds. [Step 9] A plasma is generated by the application of an RF power (second plasma process) to form a titanium nitride film (hereinafter referred to as a nitrogen rich TiN film as a first metal nitride film) 21c containing nitrogen in an amount slightly larger than a stoichiometric composition, e.g., a Ti₁N_{1.1} film on the surface of the plasma reaction Ti film 21b. The RF power is, e.g., 800 W, and a nitridation process time is, e.g., 25 to 75 seconds. [Step 10] The application of the RF power is stopped, and the introduction of the NH₃ gas into the chamber is further stopped. Then, the NH₃ gas is exhausted from the chamber.

By the first film deposition method described above, the barrier metal film 21 comprised of the thermal reaction Ti film 21a, the plasma reaction Ti film 21b, and the nitrogen rich TiN film 21c is formed. The thickness of the thermal reaction Ti film 21a is, e.g., not more than 1 nm. The thickness of the plasma reaction Ti film 21b is, e.g., 5 nm. The thickness of the nitrogen rich TiN film 21c is in a range of, e.g., 3 to 5 nm.

The thermal reaction Ti film 21a can achieve a low contact resistance with the nickel silicide layer 18. The conceivable causes thereof include: (1) the generation of (Ni₁Ti₁₋ₓ)Si at the interface between the nickel silicide layer 18 and the thermal reaction Ti film 21a; (2) the concentration of an impurity contained in the thermal reaction Ti film 21a which is lower than the impurity concentration of the plasma reaction Ti film 21b due to the generation of pure titanium by a pyrolysis reaction using nickel silicide as a catalyst; and (3) the reduction of titanium chloride by an extremely small amount of remaining fluorine resulting from the dry cleaning process. The nitrogen rich TiN film 21c is effective as a barrier film which suppresses or prevents the diffusion of atoms composing a plug. In addition, by the plasma process of Step 6, the concentration of an impurity such as chlorine in the plasma reaction Ti film 21b is reduced.

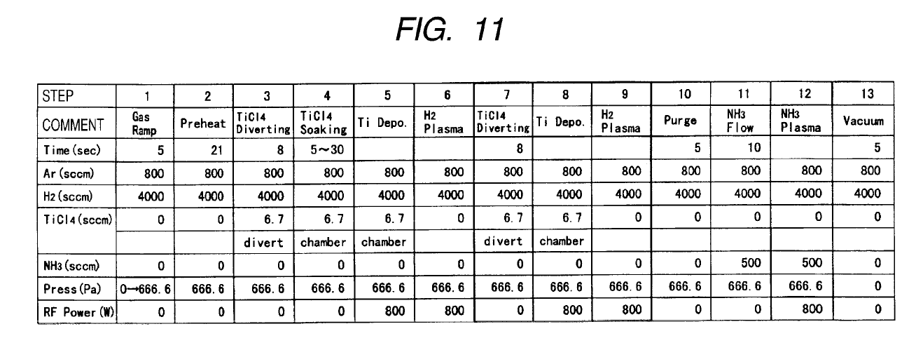

The second film deposition method for the barrier metal film 21 will be described with reference to FIGS. 11 and 14.

The second film deposition method is the same as the first film deposition method described above from [Step 1] to [Step 6], so that the description thereof is omitted herein. However, the film deposition time of the plasma reaction Ti film 21b in Step 5 is, e.g., 5 seconds.

[Step 7] A TiCl₄ gas is supplied from a TiCl₄ gas supply source, and caused to flow to the outside immediately before reaching the chamber till the flow rate thereof is stabilized. The flow rate of the TiCl₄ gas is, e.g., 6.7 sccm. [Step 8] After the flow rate of the TiCl₄ gas is stabilized, the TiCl₄ gas is introduced into the chamber, and an a plasma is generated within the chamber by the application of an RF power to further form the plasma reaction Ti film 21b over the plasma reaction Ti film 21b. The flow rate of the TiCl₄ gas is, e.g., 6.7 sccm. The RF power is, e.g., 800 W. A film deposition time is, e.g., 5 seconds. The thickness of the plasma reaction Ti film 21b is in a range of, e.g., 1 to 2 nm. [Step 9] Only the introduction of the TiCl₄ gas into the chamber is stopped, and a plasma process using a H₂ gas is performed with respect to the plasma reaction Ti film 21b to reduce the chlorine concentration of the plasma reaction Ti film 21b. A plasma process time is, e.g., 5 seconds. The process of [Step 7] to [Step 9] is repeated a plurality of times, e.g., four times. The total thickness of the plasma reaction Ti films 21b is in a range of, e.g., 5 to 10 nm.

[Step 10] The application of the RF power is stopped, and the TiCl₄ gas is exhausted from the inside of the chamber. [Step 11] A NH₃ gas is introduced into the chamber to nitride the surface of the plasma reaction Ti film 21b by a thermal reaction. The flow rate of the NH₃ gas is, e.g., 500 sccm, and a heating process time is, e.g., 10 seconds. [Step 12] A plasma is generated by the application of an RF power to form the nitrogen rich TiN film 21c on the surface of the plasma reaction Ti film 21b. The RF power is, e.g., 800 W, and a nitridation process time is, e.g., 25 to 75 seconds. [Step 13] The application of the RF power is stopped, and the introduction of the NH₃ gas into the chamber is further stopped. Then, the NH₃ gas is exhausted from the chamber.

By the second film deposition method described above, the barrier metal film 21 comprised of the thermal reaction Ti film 21a, the plasma reaction Ti films 21b (in multiple levels), and the nitrogen rich TiN film 21c is formed. The thickness of the thermal reaction Ti film 21a is, e.g., not more than 1 nm. The thickness of the plasma reaction Ti films 21b is, e.g., 5 nm. The thickness of the nitrogen rich TiN film 21c is in a range of, e.g., 3 to 5 nm.

In the same manner as in the first film deposition method described above, the thermal reaction Ti film 21a can achieve a low contact resistance with the nickel silicide layer 18, and the nitrogen rich TiN film 21c is effective as a barrier film which suppresses or prevents the diffusion of atoms composing the plug. By further alternately performing the deposition of the plasma reaction Ti film 21b and the reduction thereof in a relatively short period of time in the process of (Steps 5 and 6)+(Steps 7, 8, and 9)×4, the concentration of an impurity such as chlorine can be reduced not only in the surface of the plasma reaction Ti film 21b, but also in the inside thereof. As a result, the plasma reaction Ti film 21b having a low resistivity and an excellent quality can be obtained.

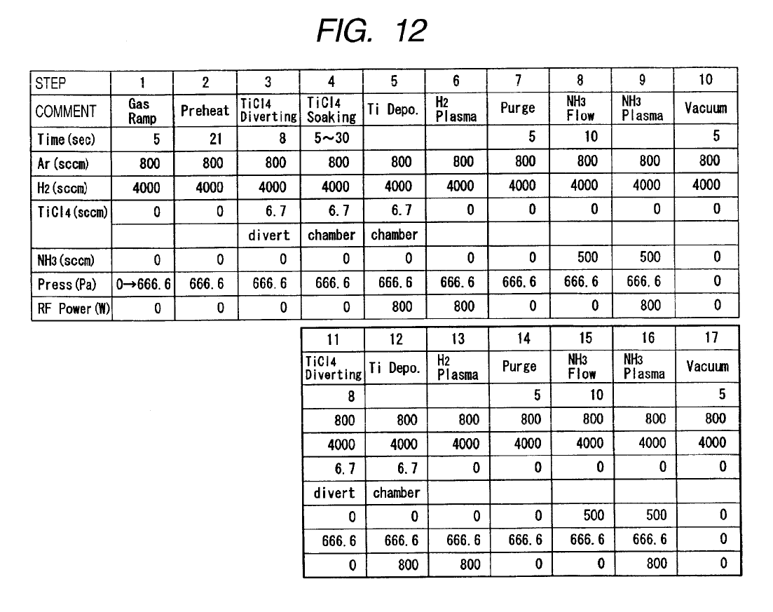

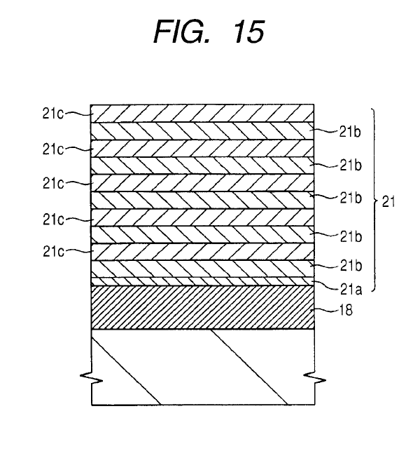

The third film deposition method for the barrier metal film 21 will be described with reference to FIGS. 12 and 15.

The third film deposition method is the same as the first film deposition method described above from [Step 1] to [Step 10], so that the description thereof is omitted herein. However, the film deposition time of the plasma reaction Ti film 21b in Step 5 is, e.g., 5 seconds, and the nitridation heating process time in Step 10 is, e.g., 5 seconds

[Step 11] A TiCl₄ gas is supplied from a TiCl₄ gas supply source, and caused to flow to the outside immediately before reaching the chamber till the flow rate thereof is stabilized. The flow rate of the TiCl₄ gas is, e.g., 6.7 sccm. [Step 12] After the flow rate of the TiCl₄ gas is stabilized, the TiCl₄ gas is introduced into the chamber, and a plasma is generated within the chamber by the application of an RF power to form a plasma reaction Ti film 21b is formed over the nitrogen rich TiN film 21c. The flow rate of the TiCl₄ gas is, e.g., 6.7 sccm. The RF power is, e.g., 800 W. A film deposition time is, e.g., 5 seconds. The thickness of the plasma reaction Ti film 21b is in a range of, e.g., 1 to 2 nm. [Step 13] Only the introduction of the TiCl₄ gas into the chamber is stopped, and a plasma process using a H₂ gas is performed with respect to the plasma reaction Ti film 21b to reduce the chlorine concentration of the plasma reaction Ti film 21b. A plasma process time is, e.g., 5 seconds. [Step 14] The application of the RF power is stopped, and the TiCl₄ gas is exhausted from the inside of the chamber. [Step 15] A NH₃ gas is introduced into the chamber to nitride the surface of the plasma reaction Ti film 21b by a thermal reaction. The flow rate of the NH₃ gas is, e.g., 500 sccm, and a heating process time is, e.g., 10 seconds. [Step 16] A plasma is generated by the application of an RF power to form the nitrogen rich TiN film 21c on the surface of the plasma reaction Ti film 21b. The RF power is, e.g., 800 W, and a nitridation process time is, e.g., 5 seconds. [Step 17] The application of the RF power is stopped, and the introduction of the NH₃ gas into the chamber is further stopped. Then, the NH₃ gas is exhausted from the chamber. The process of [Step 11] to [Step 17] is repeated a plurality of times, e.g., four times.

By the third film deposition method described above, the barrier metal film 21 comprised of the thermal reaction Ti film 21a, the five plasma reaction Ti films 21b, and the five nitrogen rich TiN films 21c is formed. The thickness of the thermal reaction Ti film 21a is, e.g., not more than 1 nm. The total thickness of the five plasma reaction Ti films 21b and the five nitrogen rich TiN films 21c is in a range of, e.g., 5 to 10 nm.

In the same manner as in the first film deposition method described above, the thermal reaction Ti film 21a can achieve a low contact resistance with the nickel silicide layer 18, and the nitrogen rich TiN film 21c is effective as a barrier film which suppresses or prevents the diffusion of atoms composing the plug. By further performing a sequential process of the deposition of the plasma reaction Ti film 21b and the nitridation thereof a plurality of times in a relatively short period of time in the process of (Steps 5, 6, 7, 8, 9, and 10)+(Steps 11, 12, 13, 14, 15, 16, and 17)×4, it is possible to obtain the plasma reaction Ti films 21b each having a low resistivity and an excellent quality resulting from a reduction in the concentration of an impurity such as chlorine, and simultaneously deposit the nitrogen rich TiN films 21c which effectively function as barrier films on the surfaces thereof.

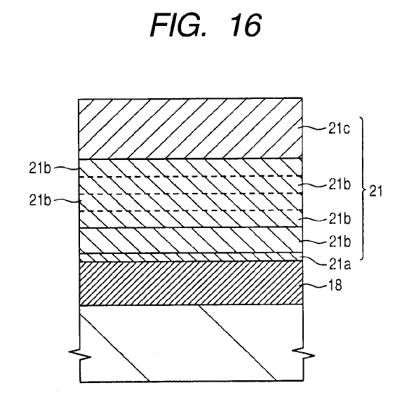

The fourth film deposition method for the barrier metal film 21 will be described with reference to FIGS. 11 and 16.

The fourth film deposition method is the same as the second film deposition method described above from [Step 1] to [Step 6], so that the description thereof is omitted herein. However, the fourth film deposition method is different in that the film deposition time of the plasma reaction Ti film 21b in Step 5 is in a range of, e.g., 5 to 15 seconds, and the thickness of the first-level plasma reaction Ti film 21b is larger than the thickness of the first-level plasma reaction Ti film 21b in the second film deposition method described above. The fourth film deposition method is also the same as the second film deposition method described above from [Step 7] to [Step 13], so that the description thereof is omitted herein.

By the fourth film deposition method described above, the barrier metal film 21 comprised of the thermal reaction Ti film 21a, the plasma reaction Ti film 21b, the plasma reaction Ti film 21b (in multiple levels), and the nitrogen rich TiN film 21c is formed. The thickness of the thermal reaction Ti film 21a is, e.g., not more than 1 nm. The thickness of the plasma reaction Ti film 21b located in the lower layer is, e.g., 3 nm. The thickness of the plasma reaction Ti film 21b located in the upper layer is in a range of, e.g., 4 to 5 nm.

In the same manner as in the first film deposition method described above, the thermal reaction Ti film 21a can achieve a low contact resistance with the nickel silicide layer 18. The nitrogen rich TiN film 21c is effective as a barrier film which suppresses or prevents the diffusion of atoms composing the plug. By further performing the deposition of the plasma reaction Ti films 21b and the reduction thereof in a relatively short period of time in the process of [Steps 5 and 6] and [Steps 7, 8, and 9], it is possible to obtain the plasma reaction Ti films 21b each having a low resistivity and an excellent quality resulting from a reduction in the concentration of an impurity such as chlorine.

Since any of the first to fourth film deposition methods allows the formation of the barrier metal film 21 which is low in the concentration of an impurity such as chlorine, the resistance of the nickel silicide layer 18 is reduced. Therefore, it is possible to further prevent the delamination of the barrier metal film 21, a micro-crack occurring therein, and the like.

Thereafter, the semiconductor wafer SW is vacuum transported by the transfer robot 61 from the chamber 56 (or the chamber 57) for depositing a barrier metal film to any of the load lock chambers 53, and further returned by the transport robot 62 from the load lock chamber 53 to any of the FOUPs 59 via the wafer transport-in/out chamber 58.

Each of the barrier metal films 21 formed by the first to fourth film deposition methods is effective as a barrier film which suppresses or prevents the diffusion of atoms composing the plug, and has the nitrogen rich TiN film 21c. However, it is also possible to impart a higher barrier function by forming a titanium nitride film (second metal nitride film) having a thickness of, e.g., 0 to 5 nm over the barrier metal film 21 by a thermal CVD method using, e.g., a TiCl₄ gas and a NH₃ gas (fourth reaction gas) at a temperature of about 450 to 480° C. A brief description will be given hereinbelow of a film deposition method for the titanium nitride film formed over the barrier metal film 21 by the thermal CVD method with reference to FIG. 17. The titanium nitride film may be deposited in a chamber which is further coupled to the film deposition apparatus 50 mentioned above, or may be deposited using a CVD apparatus different from the film deposition apparatus 50 mentioned above. The film deposition method for the titanium nitride film is not limited thereto, and can be variously changed.

[Step 1] First, the semiconductor wafers SW are placed on a stage heated to a predetermined temperature of, e.g., 480° C. by a heater. During the period from Step 1 to Step 12, the stage is constantly heated at a predetermined temperature. Then, a N₂ gas, which is a carrier gas for each of a TiCl₄ gas and a NH₃ gas, and the NH₃ gas are introduced into the chamber to establish a predetermined pressure within the chamber in a predetermined time set in Step 1 by means of an exhaust mechanism. [Step 2] After the pressure and the flow rates of the N₂ gas and the NH₃ gas are set to the predetermined values, the wafer is heated for a predetermined time. [Step 3] At the same time, a TiCl₄ gas is supplied from a TiCl₄ gas supply source, and caused to flow to the outside immediately before reaching the chamber till the flow rate thereof is stabilized.

[Steps 4 to 10] When the titanium nitride film is deposited using the TiCl₄ gas and the NH₃ gas, the TiCl₄ gas and the NH₃ gas are simultaneously introduced into the chamber. The flow rate of each of the TiCl₄ gas and the NH₃ gas is, e.g., 60 sccm, and the pressure thereof is, e.g., 260 Pa. A deposition time is, e.g., 6 seconds. When the titanium nitride film is deposited thick, the process of [Steps 4 to 10] is repeated a plurality of times. By repeating the process of [Steps 4 to 10], e.g., six times, the titanium nitride film with a thickness of 5 nm can be formed.

[Steps 11 and 12] The application of the RF power is stopped, and the introduction of the TiCl₄ gas and the NH₃ gas into the chamber is further stopped. Then, the N₂ gas is introduced into the chamber, and the TiCl₄ gas and the NH₃ gas are exhausted from the inside of the chamber. Thereafter, the introduction of the N₂ gas into the chamber is stopped, and the chamber is evacuated.

Next, as shown in FIG. 18, a tungsten film 22 is deposited over the principal surface of the semiconductor substrate 1 including the inside of each of the coupling holes 20. In the deposition of the tungsten film 22, a core film of tungsten (hereinafter referred to as a tungsten core film as a metal film) 22a is formed first over the barrier metal film 21. Then, a tungsten film (hereinafter referred to as a blanket tungsten film as a metal film) 22b is deposited to be buried within the coupling hole 20. In the present embodiment, the tungsten core film 22a mentioned above is formed in a multilayer structure with a thickness of not more than 10 nm. The tungsten core film 22a exhibits an excellent adhesion to the nitrogen rich TiN film 21c located in the uppermost layer of the barrier metal film 21, and also has the function of suppressing or preventing fluorine contained in a WF₆ gas as a tungsten film deposition gas from entering the barrier metal film 21. Therefore, it is possible to prevent the corrosion (such as, e.g., expansion or delamination of the plasma reaction Ti film 21b) of the barrier metal film 21 by fluorine.

A description will be given herein of each of first, second, and third film deposition methods for the tungsten film 22. In the first film deposition method, a WF₆ gas, a SiH₄ gas, and a H₂ gas are simultaneously supplied into the chamber to form the tungsten core film 22a, and then form the blanket tungsten film 22b. In the second film deposition method, after tungsten and fluorine are caused to be adsorbed on the surface of the barrier metal film 21 using a WF₆ gas, the tungsten core film 22a is formed by removing fluorine by a reduction reaction using a SiH₄ gas, and then the blanket tungsten film 22b is formed. In the third film deposition method, after tungsten and fluorine are caused to be adsorbed on the surface of the barrier metal film 21 using a WF₆ gas, the tungsten core film 22a is formed by removing fluorine by a reduction reaction using a B₂H₆ gas, and then the blanket tungsten film 22b is formed. The film deposition method for the tungsten film 22 (the tungsten core film 22a and the blanket tungsten film 22b) is not limited thereto, and can be variously changed.

The first film deposition method is implemented as follows in accordance with, e.g., the process steps shown in FIG. 19.

[Steps 1 and 2] The WF₆ gas (fifth reaction gas), the SiH₄ gas, and the H₂ gas (first reduction) are introduced into the chamber at respective predetermined flow rates to form the tungsten core film 22a with a predetermined thickness (A1) on the surface of the barrier metal film 21. It is assumed that the pressure within the chamber is, e.g., 2667 Pa, and the temperature of each of the semiconductor wafers is, e.g., 390° C. The tungsten core film 22a having a desired thickness is formed by controlling the time (A1) of Step 2. The thickness of the tungsten core film 22a is, e.g., 7 nm. Since fluorine can be removed simultaneously with the film deposition by simultaneously introducing the WF₆ gas and the SiH₄ gas into the chamber, the tungsten core film 22a containing a small amount of fluorine can be formed.

[Steps 3 to 6] After the H₂ gas (second reduction gas) is introduced into the chamber at a predetermined flow rate, the WF₆ gas (sixth reaction gas) is introduced into the chamber at a predetermined flow rate of, e.g., 250 sccm to form the blanket tungsten film 22b over the tungsten core film 22a by a H₂ reduction. It is assumed that the pressure within the chamber is, e.g., 10666 Pa, and the temperature of the semiconductor wafer is not more than 400° C., and is, e.g., 390° C. The blanket tungsten film 22b having a desired thickness is formed by controlling the time (A2) of Step 5. The thickness of the blanket tungsten film 22b is, e.g., 193 nm. After the blanket tungsten film 22b is formed, the pressure is set to 0 Pa, and the flow rate of the WF₆ gas is set to 0 sccm.

In accordance with the first film deposition method using core formation by the SiH₄ reduction mentioned above, the tungsten film 22 comprised of the tungsten core film 22a and the blanket tungsten film 22b and containing a small amount of fluorine is formed. The deposition temperature of the blanket tungsten film 22b is, e.g., 390° C. By depositing the tungsten film 22 at a relatively low temperature of not more than 400° C., the entrance of fluorine contained in the WF₆ gas during the deposition of the blanket tungsten film 22b can be suppressed. As a result, it is possible to suppress or prevent the entrance of fluorine contained in the WF₆ gas into the barrier metal film 21, and thereby prevent the corrosion of the barrier metal film 21 by fluorine.

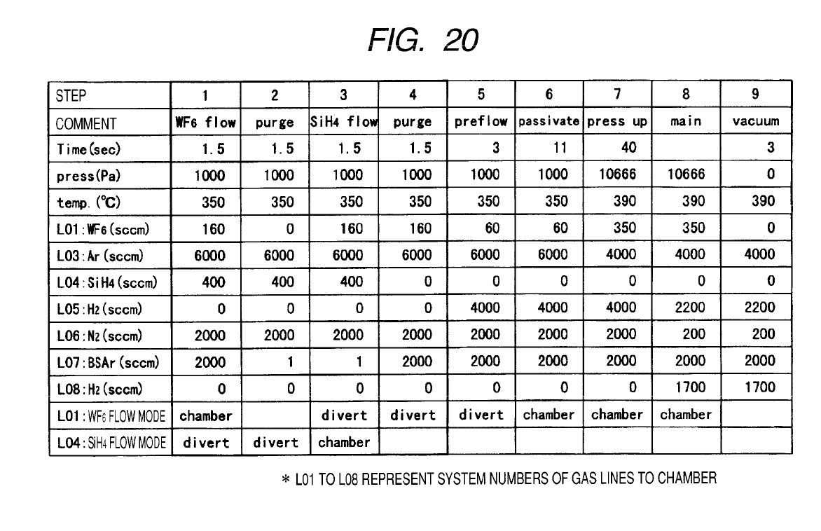

The second film deposition method is implemented as follows in accordance with, e.g., the process steps shown in FIG. 20.

[Steps 1 and 2] The WF₆ gas (fifth reaction gas) is introduced into the chamber at a predetermined flow rate of, e.g., 160 sccm to form the tungsten core film having a thickness of about 1 nm by causing tungsten and fluorine to be adsorbed on the surface of the barrier metal film 21. The pressure within the chamber is, e.g., 1000 Pa, and the temperature of each of the semiconductor wafers is, e.g., 350° C. Thereafter, the supply of the WF₆ gas into the chamber is stopped.

[Steps 3 and 4] The SiH₄ gas (first reduction gas) is introduced into the chamber at a predetermined flow rate of, e.g., 400 sccm to remove fluorine in the foregoing tungsten core film by a SiH₄ reduction. The pressure within the chamber is, e.g., 1000 Pa, and the temperature of the semiconductor wafer is, e.g., 350° C. Thereafter, the supply of the SiH₄ gas into the chamber is stopped. By repeating the process of [Steps 1 to 4] a plurality of times, e.g., seven times, the tungsten core film 22a having a multilayer structure is formed. The thickness of the tungsten core film 22a is, e.g., 7 nm.

[Steps 5 to 9] After the H₂ gas (second reduction gas) is introduced into the chamber at a predetermined flow rate of, e.g., 4000 sccm, the WF₆ gas (sixth reaction gas) is introduced into the chamber at a predetermined flow rate of, e.g., 60 sccm. Subsequently, the flow rate of the WF₆ gas is increased to, e.g., 350 sccm, and the pressure is increased to, e.g., 10666 Pa. The temperature of the semiconductor wafer is also increased to be not more than 400° C., e.g., 390° C. Thereafter, the blanket tungsten film 22b is formed over the tungsten core film 22a by a H₂ reduction. After the formation of the blanket tungsten film 22b having a desired thickness, the pressure is set to 0 Pa, and the flow rate of the WF₆ gas is set to 0 sccm. The thickness of the blanket tungsten film 22 is, e.g., 193 nm.

In accordance with the second film deposition method using core formation by the SiH₄ reduction mentioned above, the tungsten film 22 comprised of the tungsten core film 22a and the blanket tungsten film 22b is formed. By forming the tungsten core film 22a in the multilayer structure, the interface between the individual layers becomes discontinuous so that fluorine contained in the WF₆ gas is less likely to be transmitted by the tungsten core film 22a during the deposition of the blanket tungsten film 22b. The deposition temperature of the blanket tungsten film 22b is, e.g., 390° C. By depositing the tungsten film 22 at a relatively low temperature of not more than 400° C., the entrance of fluorine contained in the WF₆ gas during the deposition of the blanket tungsten film 22b can be suppressed. As a result, it is possible to suppress or prevent the entrance of fluorine contained in the WF₆ gas into the barrier metal film 21, and thereby prevent the corrosion of the barrier metal film 21 by fluorine.

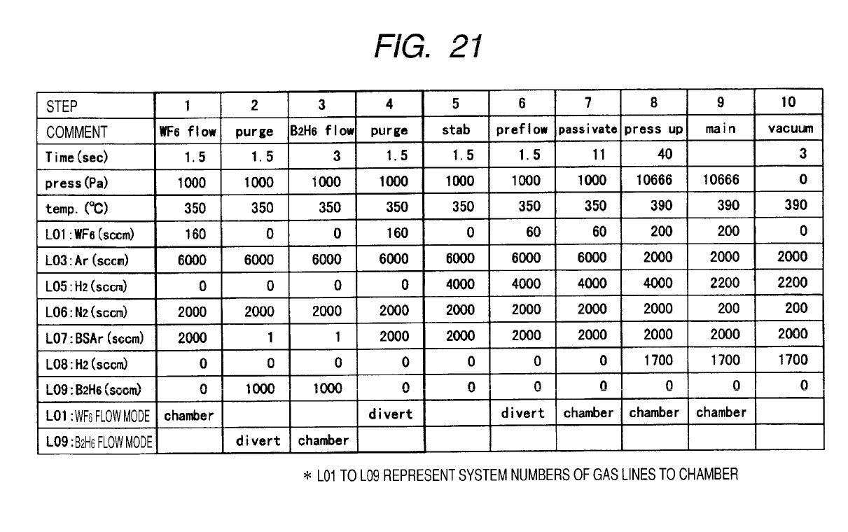

The third film deposition method is implemented as follows in accordance with, e.g., the process steps shown in FIG. 21.

[Steps 1 and 2] The WF₆ gas (fifth reaction gas) is introduced into the chamber at a predetermined flow rate of, e.g., 160 sccm to form the tungsten core film having a thickness of about 1 nm by causing tungsten and fluorine to be adsorbed on the surface of the barrier metal film 21. The pressure within the chamber is, e.g., 1000 Pa, and the temperature of each of the semiconductor wafers is, e.g., 350° C. Thereafter, the supply of the WF₆ gas into the chamber is stopped.

[Steps 3 and 4] A 5% B₂H₆ gas (first reduction gas) diluted with a H₂ gas is introduced into the chamber at a predetermined flow rate of, e.g., 1000 sccm to remove fluorine in the foregoing tungsten core film by a B₂H₆ reduction. The pressure within the chamber is, e.g., 1000 Pa, and the temperature of the semiconductor wafer is, e.g., 350° C. Thereafter, the supply of the 5% B₂H₆ gas diluted with the H₂ gas into the chamber is stopped. By repeating the process of [Steps 1 to 4] a plurality of times, e.g., eight times, the tungsten core film 22a having a multilayer structure is formed. The thickness of the tungsten core film 22a is, e.g., 7 nm, and the structure thereof is amorphous.

[Steps 5 to 10] After the H₂ gas (second reduction gas) is introduced into the chamber at a predetermined flow rate of, e.g., 4000 sccm, the WF₆ gas (sixth reaction gas) is introduced into the chamber at a predetermined flow rate of, e.g., 60 sccm. Subsequently, the flow rate of the WF₆ gas is increased to, e.g., 200 sccm, and the pressure is increased to, e.g., 10666 Pa. The temperature of the semiconductor wafer is also increased to be not more than 400° C., e.g., 390° C. Thereafter, the blanket tungsten film 22b is formed over the tungsten core film 22a by a H₂ reduction. After the formation of the blanket tungsten film 22b having a desired thickness, the pressure is set to 0 Pa, and the flow rate of the WF₆ gas is set to 0 sccm. The thickness of the blanket tungsten film 22 is, e.g., 193 nm.

In accordance with the third film deposition method using core formation by the B₂H₆ reduction mentioned above, the tungsten film 22 comprised of the tungsten core film 22a and the blanket tungsten film 22b is formed. By forming the tungsten core film 22a in the multilayer structure in the same manner as in the second film deposition method using core formation by the SiH₄ reduction mentioned above, the interface between the individual layers becomes discontinuous. In addition, since the structure of the tungsten core film 22a is amorphous, fluorine contained in the WF₆ gas is less likely to be transmitted by the tungsten core film 22a during the deposition of the blanket tungsten film 22b. The deposition temperature of the blanket tungsten film 22b is, e.g., 390° C. By depositing the tungsten film 22 at a relatively low temperature of not more than 400° C., the entrance of fluorine contained in the WF₆ gas during the deposition of the blanket tungsten film 22b can be suppressed. As a result, it is possible to suppress or prevent the entrance of fluorine contained in the WF₆ gas into the barrier metal film 21, and thereby prevent the corrosion of the barrier metal film 21 by fluorine.

Next, as shown in FIG. 22, the tungsten film 22 and the barrier metal film 21 in the region other than the inside of each of the coupling holes 20 are removed by polishing the surface of the tungsten film 22 by, e.g., a CMP method so that the tungsten film 22 is buried within the coupling hole 20 to form the plug in which the tungsten film 22 is the main conductive material.

In the step of forming the plug within the coupling hole 20 described above, the tungsten film 22 is used as the main conductive material of the plug, and the barrier metal film 21 is formed as a multilayer film obtained by forming the titanium nitride film 21c over the titanium films 21a and 21b. However, the plug and the barrier metal film are not limited thereto, and can be variously changed. For example, it is also possible to use the barrier metal film 21 mentioned above as the barrier metal film, and use a copper film as the main conductive material of the plug. In this case, the barrier metal film 21 is deposited first in the same manner as in the manufacturing method described above, and then a seed layer, e.g., a seed layer of copper or ruthenium is formed over the barrier metal film 21 by a CVD method or a sputtering method. By further forming a copper plating film over the seed layer using an electrolytic plating method, the copper plating film is buried within the coupling hole 20.

Next, as shown in FIG. 23, a stopper insulating film 24 and an insulating film 25 for interconnect formation are successively formed over the principal surface of the semiconductor substrate 1. The stopper insulating film 24 serves as an etching stopper when a trenching process is performed with respect to the insulating film 25, and uses a material having an etching selectivity with respect to the insulating film 25. The stopper insulating film 24 can be made of, e.g., a silicon nitride film formed by a plasma CVD method, and the insulating film 25 can be made of, e.g., a silicon dioxide film formed by a plasma CVD method. The stopper insulating film 24 and the insulating film 25 are formed with a first-layer interconnect which will be described next.

Next, the first-layer interconnect is formed by a single damascene method. First, an interconnect trench 26 is formed in the predetermined regions of the stopper insulating film 24 and the insulating film 25 by dry etching using a resist pattern as a mask. Then, a barrier metal film 27 is formed over the principal surface of the semiconductor substrate 1. For example, the barrier metal film 27 is a titanium nitride film, a tantalum nitride film, a multilayer film obtained by stacking a tantalum film over a tantalum nitride film, or a multilayer film obtained by stacking a ruthenium film over a tantalum nitride film. Subsequently, a seed layer of copper is formed over the barrier metal film 27 by a CVD method or a sputtering method, and a copper plating layer is further formed over the seed layer using an electrolytic plating method. The copper plating film is buried within the interconnect trench 26. Subsequently, the copper plating film, the seed layer, and the barrier metal film 27 in the region other than the interconnect trench 26 are removed by a CMP method to form a first-layer interconnect M1 in which the copper film is the main conductive material.

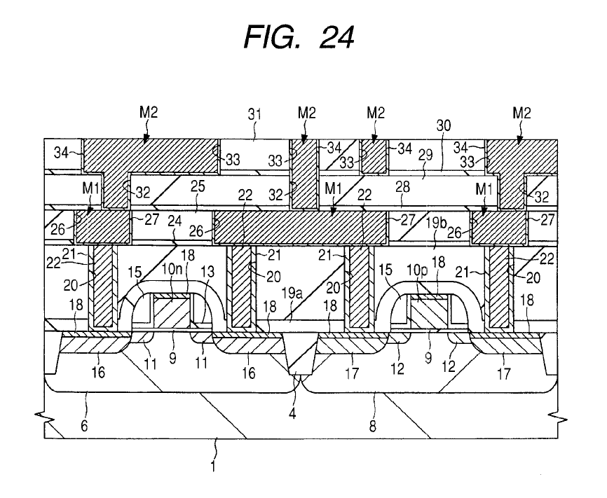

Next, a second-layer interconnect is formed by a dual damascene method. First, as shown in FIG. 24, a cap insulating film 28, an interlayer insulating film 29, and a stopper insulating film 30 for interconnect formation are successively formed over the principal surface of the semiconductor substrate 1. As will be described later, coupling holes are formed in the cap insulating film 28 and the interlayer insulating film 29. The cap insulating film 28 is made of a material having an etching selectivity with respect to the interlayer insulating film 29. For example, the cap insulating film 28 can be made of a silicon nitride film formed by a plasma CVD method. The cap insulating film 28 further has a function as a protective film which prevents the diffusion of copper composing the first-layer interconnect M1. For example, the interlayer insulating film 29 can be made of a TEOS film formed by a plasma CVD method. The stopper insulating film 30 is made of an insulating material having an etching selectivity with respect to the interlayer insulating film 29, and to an insulating film for interconnect formation which is subsequently deposited in a layer over the stopper insulating film 30. For example, the stopper insulating film 30 can be made of a silicon nitride film formed by a plasma CVD method.

Next, after the stopper insulating film 30 is processed by dry etching using a resist pattern for hole formation as a mask, an insulating film 31 for interconnect formation is formed over the stopper insulating film 30. For example, the insulating film 31 can be made of a TEOS film.

Next, an insulating film 31 is processed by dry etching using a resist pattern for interconnect trench formation as a mask. At this time, the stopper insulating film 30 functions as an etching stopper. Subsequently, the interlayer insulating film 29 is processed by dry etching using the stopper insulating film 30 and the resist pattern for interconnect trench formation as a mask. At this time, the cap insulating film 28 functions as an etching stopper. Subsequently, by removing the exposed cap insulating film 28 by dry etching, coupling holes 32 are formed in the cap insulating film 28 and the interlayer insulating film 29, and interconnect trenches 33 are formed in the stopper insulating film 30 and the insulating film 31.

Next, the second-layer interconnect is formed within each of the coupling holes 32 and the interconnect trenches 33. The second-layer interconnect is made of a barrier metal layer and a copper film as the main conductive material. A coupling member for coupling the interconnect and the first-layer interconnect M1 as the lower-layer interconnect is formed integrally with the second-layer interconnect. First, a barrier metal film 34 is formed over the principal surface of the semiconductor substrate 1 including the inside of each of the coupling holes 32 and the interconnect trenches 33. For example, the barrier metal film 34 is a titanium nitride film, a tantalum nitride film, a multilayer film obtained by stacking a tantalum film over a tantalum nitride film, or a multilayer film obtained by stacking a ruthenium film over a tantalum nitride film. Prior to the formation of the barrier metal film 34, the dry cleaning process described above is performed. However, even in the dry cleaning process, it is also possible to subsequently perform the heating at a temperature ranging from 100 to 150° C. described above, and heating at a temperature higher than 150° C. with respect to each of the semiconductor wafers, and remove a product produced at the bottom surfaces of the coupling holes 32 and at the side walls of the coupling holes 32 and the interconnect trenches 33. This can reduce fluctuations in the contact resistance between the barrier metal film 34 and the first-layer interconnect M1, and prevent the delamination of the barrier metal film 34 from the cap insulating film 28, the interlayer insulating film 29, the stopper insulating film 30, and the insulating film 31. Subsequently, a seed layer of copper is formed over the barrier metal film 34 by a CVD method or a sputtering method, and a copper plating film is further formed over the seed layer using an electrolytic plating method. The copper plating film is buried in each of the coupling holes 32 and the interconnect trenches 33. Subsequently, the copper plating film, the seed layer, and the barrier metal film 34 in the region other than the coupling holes 32 and the interconnect trenches 33 are removed by a CMP method to form a second-layer interconnect M2 in which the copper film is the main conductive material.

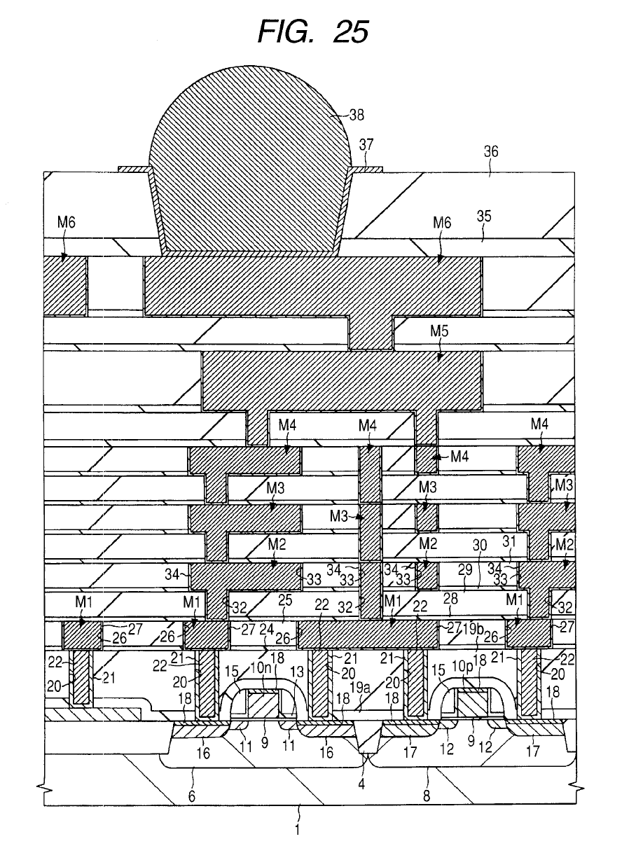

Thereafter, as shown in FIG. 25, a further-upper-layer interconnect is formed by the same method as used to form, e.g., the second-layer interconnect M2 described above. FIG. 25 illustrates a CMOS device in which third- to sixth-layer interconnects M3, M4, M5, and M6 are formed. Subsequently, a silicon nitride film 35 is formed over the sixth-layer interconnect M6, and a silicon dioxide film 36 is formed over the silicon nitride film 35. The silicon nitride film 35 and the silicon dioxide film 36 function as passivation films which prevent the entrance of moisture and an impurity from the outside, and suppress the transmission of an alpha ray.

Next, the silicon nitride film 35 and the silicon dioxide film 36 are processed by etching using a resist pattern as a mask to expose a portion (bonding pad portion) of the sixth-layer interconnect M6. Subsequently, a bump base electrode 37 made of a multilayer film of a gold film, a nickel film, and the like is formed over the exposed sixth-layer interconnect M6, and a bump electrode 38 made of gold, a solder, or the like is formed over the bump base electrode 37, whereby the CMOS device as the present embodiment is generally completed. The bump electrode 38 serves as an electrode for external coupling. Thereafter, the semiconductor wafer SW is cut and divided into individual semiconductor chips. Each of the semiconductor chips is mounted on a package substrate or the like to complete a semiconductor device, but the description thereof is omitted.

Thus, according to the present embodiment, it is possible to suppress the enlargement of the diameter of each of the coupling holes 20 by the dry cleaning process and the heating process which are performed before the barrier metal film 21 is formed within the coupling hole 20, and remove a natural oxide film on the surface of the nickel silicide layer 18 at the bottom surface of the coupling hole 20. By removing the natural oxide film from the surface of the nickel silicide layer 18, it is possible to prevent fluctuations or an increase in the contact resistance between the nickel silicide layer 18 and the barrier metal film 21 at the bottom surface of the coupling hole 20.

Although the invention achieved by the present inventors has thus been described specifically based on the embodiment thereof, the present invention is not limited thereto. It will be understood that various changes and modifications can be made in the invention without departing from the gist thereof.

The present invention is applicable to the manufacturing of a semiconductor device having the step of burying a conductive material within a coupling hole bored in an insulating film.

What is claimed is:

1. A method of manufacturing a semiconductor device, the method comprising the step of:
(a) forming an insulating film over a principal surface of a semiconductor wafer;
(b) forming a coupling hole in the insulating film;
(c) after the step (b), supplying reduction gases including a HF gas and a NH₃ gas to the principal surface of the semiconductor wafer; and
(d) after the step (c), performing a heating process with respect to the semiconductor wafer, wherein a flow rate ratio between the HF gas and the NH₃ gas is adjusted to be more than 1 and not more than 5 in the step (c).

2. A method of manufacturing a semiconductor device according to claim 1, wherein a temperature in the step (c) is not more than 30° C.

3. A method of manufacturing a semiconductor device according to claim 1, wherein a bottom portion of the coupling hole is opened over a nickel silicide layer, a nickel alloy silicide layer, a cobalt silicide layer, a tungsten silicide layer, or a platinum silicide layer.

4. A method of manufacturing a semiconductor device according to claim 1, wherein a product is formed by a reduction reaction over the principal surface of the semiconductor wafer including an inside of the coupling hole in the step (c).

5. A method of manufacturing a semiconductor device according to claim 4, wherein a speed of the reduction reaction is limited by a surface reaction.

6. A method of manufacturing a semiconductor device according to claim 4, wherein the product is (NH₄)₂SiF₆.

7. A method of manufacturing a semiconductor device according to claim 1, wherein the temperature of the heating process in the step (d) ranges from 150° C. to 400° C.

8. A method of manufacturing a semiconductor device according to claim 1, wherein the temperature of the heating process in the step (d) ranges from 165° C. to 350° C.

9. A method of manufacturing a semiconductor device according to claim 1, wherein the temperature of the heating process in the step (d) ranges from 180° C. to 220° C.

10. A method of manufacturing a semiconductor device according to claim 1, further comprising, after the step (d), the steps of:
(e) forming a barrier metal film over the principal surface of the semiconductor wafer including an inside of the coupling hole;
(f) forming a metal film over the principal surface of the semiconductor wafer including the inside of the coupling hole to bury the metal film within the coupling hole; and
(g) removing the metal film and the barrier metal film in a region other than the inside of the coupling hole to form a plug within the coupling hole.

11. A method of manufacturing a semiconductor device according to claim 10, wherein the barrier metal film is a laminated film obtained by successively depositing a titanium film and a titanium nitride film in layers in an upward direction.
